(19) United States
(12) Patent Application Publication
(10) Pub. No.: US 2007/0262373 A1
(43) Pub. Date: Nov. 15, 2007

(54) Non-volatile memory integrated circuit device and method of fabricating the same

(75) Inventors: Weon-ho Park, Suwon-si (KR); Jeong-uk Han, Suwon-si (KR); Yong-tae Kim, Yongin-si (KR); Tea-kwang Yu, Suwon-si (KR); Kwang-tae Kim, Suwon-si (KR); Ji-hoon Park, Seoul (KR)

Correspondence Address: MILLS & ONELLO LLP, ELEVEN BEACON STREET, SUITE 605, BOSTON, MA, 02108, US

(73) Assignee: Samsung Electronics, Co., Ltd.

(21) Appl. No.: 11/800,650

(22) Filed: May 7, 2007

(30) Foreign Application Priority Data
May 11, 2006 (KR) 10-2006-0042571

(51) Int. Cl. H01L 29/792

(52) U.S. Cl. 257/324

(57) ABSTRACT

A non-volatile memory integrated circuit device and a method of fabricating the same are disclosed. The non-volatile memory integrated circuit device includes a semiconductor substrate, a tunneling dielectric layer, a memory gate and a select gate, a floating junction region, a bit line junction region and a common source region, and a tunneling-prevention dielectric layer pattern. The tunneling dielectric layer is formed on the semiconductor substrate. The memory gate and a select gate are formed on the tunneling dielectric layer to be spaced apart from each other. The floating junction region is formed within the semiconductor substrate between the memory gate and the select gate, the bit line junction region is formed opposite the floating junction region with respect to the memory gate, and a common source region is formed opposite the floating junction region with respect to the select gate. The tunneling-prevention dielectric layer pattern is interposed between the semiconductor substrate and the tunneling dielectric layer, and is configured to overlap part of the memory gate.

### CROSS-REFERENCE TO RELATED APPLICATION

This application claims priority from Korean Patent Application No. 10-2006-0042571 filed on May 11, 2006 in the Korean Intellectual Property Office, the contents of which are incorporated herein by reference in their entirety.

### BACKGROUND OF THE INVENTION

1. Field of the Invention

The present invention relates to a non-volatile memory integrated circuit device and a method of fabricating the device and, more particularly, to a non-volatile memory integrated circuit device having improved program/erase efficiency, and a method of fabricating the device.

2. Description of the Related Art

Non-volatile memory integrated circuit devices used in contact-less smart cards, such as a credit card, an Identification (ID) card, and a bank entry card, require high reliability, a short access time, and low power consumption.

To meet these requirements, a flash memory cell composed of two transistors (hereinafter referred to as a “2Tr flash memory cell”) has been developed. The 2Tr flash memory cell includes a memory transistor and a select transistor, which are connected in series. The memory transistor is connected to a bit line and the select transistor is connected to a common source. A floating junction is arranged between the memory transistor and the select transistor.

The 2Tr flash memory cell has a very short access time because it employs an NOR architecture. Furthermore, an over-erase problem rarely occurs in the 2Tr flash memory cell because the select transistor is employed. In addition, since program and erase operations are performed using FN tunneling, the current (power) during a program or erase operation can be limited and high efficiency can be achieved using low voltage.

In order to prevent program/erase efficiency from decreasing when the area of the 2Tr flash memory cell is reduced, it is required that the thickness of the inter-gate dielectric layer and the size of the tunneling region be reduced. However, the thickness of the inter-gate dielectric layer has been continuously reduced, whereas the size of the tunneling region has not been sufficiently reduced due to inherent limitations of associated processes.

### SUMMARY OF THE INVENTION

In accordance with an aspect of the present invention, a non-volatile memory integrated circuit device includes a semiconductor substrate; a tunneling dielectric layer formed on the semiconductor substrate; a memory gate and a select gate formed on the tunneling dielectric layer, the memory gate and the select gate being spaced apart from each other, a floating junction region formed within the semiconductor substrate between the memory gate and the select gate, a bit line junction region formed opposite the floating junction region with respect to the memory gate, and a common source region formed opposite the floating junction region with respect to the select gate; and a tunneling-prevention dielectric layer pattern interposed between the semiconductor substrate and the tunneling dielectric layer and configured to overlap part of the memory gate.

In one embodiment, the tunneling-prevention dielectric layer pattern is thicker than the tunneling dielectric layer. In one embodiment, the tunneling-prevention dielectric layer pattern has a thickness of about 100 to 300 \acute{Å} and the tunneling dielectric layer has a thickness of about 60 to 80 \acute{Å}.

In one embodiment, the tunneling-prevention dielectric layer pattern is a single film made of SiO₂, SiON, La₂O₃, ZrO₂ or Al₂O₃, or a stack or mixed film made of SiO₂, SiON, La₂O₃, ZrO₂, and/or Al₂O₃.

In one embodiment, the tunneling-prevention dielectric layer pattern overlaps at least part of the floating junction region. In one embodiment, the tunneling-prevention dielectric layer pattern overlaps at least part of the select gate.

In one embodiment, the tunneling-prevention dielectric layer pattern overlaps at least part of the bit line junction region.

In one embodiment, the semiconductor substrate is a first conduction type, and comprises a second conduction-type first well, which is formed within the semiconductor substrate, and a first conduction-type second well, which is formed within the first well.

In one embodiment, the memory gate has a stack structure in which a floating gate and a control gate which are electrically isolated from each other, are stacked one on top of another.

In one embodiment, the select gate has a stack structure in which a plurality of conductive films which are electrically connected to each other through a butting contact is stacked one on top of another.

In accordance with another aspect of the present invention, a non-volatile memory integrated circuit device includes a semiconductor substrate; a tunneling dielectric layer formed on the semiconductor substrate; a memory gate and a select gate formed on the tunneling dielectric layer, the memory gate and the select gate being spaced apart from each other, and a floating junction region formed within the semiconductor substrate between the memory gate and the select gate, a bit line junction region formed opposite the floating junction region with respect to the memory gate, and a common source region formed opposite the floating junction region with respect to the select gate; wherein a tunneling dielectric layer below the memory gate comprises a floating junction region-side tunneling dielectric layer and a bit line junction region-side tunneling dielectric layer having different thicknesses; and wherein any one of the floating junction region-side tunneling dielectric layer and the bit line junction region-side tunneling dielectric layer is thicker than a tunneling dielectric layer below the select gate.

In one embodiment, the floating junction region-side tunneling dielectric layer is thicker than the bit line junction region-side tunneling dielectric layer, and the tunneling dielectric layer below the select gate has a thickness identical to that of the bit line junction region-side tunneling dielectric layer.

In one embodiment, the bit line junction region-side tunneling dielectric layer is thicker than the floating junction region-side tunneling dielectric layer, and the tunneling dielectric layer below the select gate has a thickness identical to that of the floating junction region-side tunneling dielectric layer.

In one embodiment, the semiconductor substrate is a first conduction type, and comprises a second conduction-type first well, which is formed within the semiconductor substrate, and a first conduction-type second well, which is formed within the first well.

In accordance with still another aspect of the present invention, a non-volatile memory integrated circuit device includes a first conduction-type semiconductor substrate; a second conduction-type first well formed within the semiconductor substrate; a first conduction-type second well formed within the first well; a tunneling dielectric layer formed on the second well; a memory gate and a select gate formed on the tunneling dielectric layer, the memory gate and the select gate being spaced apart from each other, and a floating junction region formed within the semiconductor substrate between the memory gate and the select gate, a bit line junction region formed opposite the floating junction region with respect to the memory gate, and a common source region formed opposite the floating junction region with respect to the select gate; wherein the tunneling dielectric layer below the memory gate varies in thickness on the floating junction region side and the bit line junction region side.

In one embodiment, the tunneling dielectric layer below the memory gate is thicker on a floating junction region side than on a bit line junction region side, and the tunneling dielectric layer below the select gate has a thickness identical to that of the bit line junction region-side tunneling dielectric layer below the memory gate.

In one embodiment, the tunneling dielectric layer below the memory gate is thicker on a bit line junction region side than on a floating junction region side, and the tunneling dielectric layer below the select gate has a thickness identical to that of the floating junction region-side tunneling dielectric layer below the memory gate.

In accordance with an aspect of the present invention, a method of fabricating a non-volatile memory integrated circuit device includes forming a tunneling-prevention dielectric layer pattern on a semiconductor substrate; forming a tunneling dielectric layer on the tunneling-prevention dielectric layer pattern and the semiconductor substrate; forming a memory gate and a select gate on the tunneling dielectric layer to be spaced apart from each other, wherein part of the memory gate overlaps the tunneling-prevention dielectric layer pattern; and forming a floating junction region within the semiconductor substrate between the memory gate and the select gate, a bit line junction region opposite the floating junction region with respect to the memory gate, and a common source region opposite the floating junction region with respect to the select gate.

In one embodiment, the tunneling-prevention dielectric layer pattern overlaps at least part of the floating junction region. In one embodiment, the tunneling-prevention dielectric layer pattern overlaps at least part of the select gate.

In one embodiment, the tunneling-prevention dielectric layer pattern overlaps at least part of the bit line junction region.

In accordance with another aspect of the present invention, a method of fabricating a non-volatile memory integrated circuit device includes forming a tunneling dielectric layer on a semiconductor substrate; forming a memory gate and a select gate on the tunneling dielectric layer to be spaced apart from each other; and forming a floating junction region within the semiconductor substrate between the memory gate and the select gate, a bit line junction region opposite the floating junction region with respect to the memory gate, and a common source region opposite the floating junction region with respect to the select gate; wherein forming the tunneling dielectric layer is performed in such a way that a tunneling dielectric layer below the memory gate comprises a floating junction region-side tunneling dielectric layer and a bit line junction region-side tunneling dielectric layer, which have different thicknesses, and any one of the floating junction region-side tunneling dielectric layer and the bit line junction region-side tunneling dielectric layer is thicker than the tunneling dielectric layer below the select gate.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a circuit diagram of a non-volatile memory integrated circuit device according to embodiments of the present invention.

FIG. 2 is a layout diagram of a non-volatile memory integrated circuit device according to an embodiment of the present invention.

FIG. 3 is a diagram illustrating active regions of the device of FIG. 2.

FIG. 4 is a sectional view of the non-volatile memory integrated circuit device taken along line IV-IV′ of FIG. 2.

FIG. 5 is a perspective view illustrating the select gate of the non-volatile memory cell of a non-volatile memory integrated circuit device according to an embodiment of the present invention.

FIGS. 6 and 7 are diagrams illustrating the program operation of the non-volatile memory integrated circuit device according to an embodiment of the present invention

FIGS. 8 and 9 are diagrams illustrating the erase operation of the non-volatile memory integrated circuit device according to an embodiment of the present invention.

FIG. 10 is a diagram illustrating the coupling ratio of a non-volatile memory cell used in a conventional non-volatile memory integrated circuit device and the coupling ratio of the non-volatile memory cell used in the non-volatile memory integrated circuit device according to an embodiment of the present invention.

FIG. 11 is a sectional view of a non-volatile memory integrated circuit device according to another embodiment of the present invention.

FIG. 12 is a sectional view of a non-volatile memory integrated circuit device according to still another embodiment of the present invention.

FIG. 13 is a sectional view of a non-volatile memory integrated circuit device according to still another embodiment of the present invention.

FIGS. 14A to 17B are diagrams illustrating a method of fabricating a non-volatile memory cell constituting part of the non-volatile memory integrated circuit device according to an embodiment of the present invention.

FIG. 18 is a sectional view illustrating a method of fabricating a non-volatile memory integrated circuit device according to another embodiment of the present invention.

### DESCRIPTION OF THE PREFERRED EMBODIMENTS

Merits and novel characteristics of the invention will become more apparent from the following detailed description and exemplary embodiments taken in conjunction with the accompanying drawings. However the present invention is not limited to the disclosed embodiments, but may be implemented in various manners. The embodiments are provided to complete the description of the present invention and to allow those having ordinary skill in the art to understand the scope of the present invention. The present invention is defined only by the claims. The same reference numbers will be used throughout the drawings to refer to the same or like parts.

The present invention is described in detail in connection with preferred embodiments with reference to the accompanying drawings.

Hereinafter, the program operation refers to an operation of charging a floating gate with electric charges, and the erase operation refers to an operation of discharging electric charges from a floating gate. However, it will be apparent to those skilled in the art that, depending on the operation of an integrated circuit device, the discharging of a floating gate with electric charges may be a program operation and the charging of electric charges from a floating gate can be an erase operation.

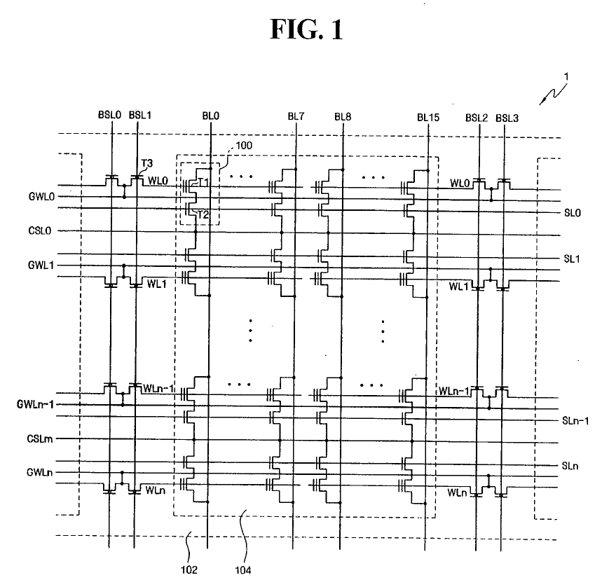

FIG. 1 is a circuit diagram of a non-volatile memory integrated circuit device 1 according to embodiments of the present invention. Referring to FIG. 1, in the non-volatile memory integrated circuit device 1 according to the embodiments of the present invention, cell blocks in which a plurality of non-volatile memory cells 100 are arranged according to a NOR architecture are arranged in a repeating manner. The non-volatile memory cell 100 includes a memory transistor T1 having a floating gate and a control gate, and a select transistor T2 having a select gate. The control gates of a plurality of memory transistors T1 located along the same row are interconnected by one of word lines WL0 to WLn, and the select gates of a plurality of select transistors T2 located along the same row are interconnected by one of select lines SL0 to SLn. Furthermore, a plurality of memory transistors T1 located along the same column can be connected by one of bit lines BL0 to BL15. A plurality of select transistors T2 is interconnected by common source lines CSL0 to CSLm. The common source lines CSL0 to CSLm may be constructed to be each shared by each row, each pair of rows, or each cell block.

Global word lines GWL0 to GWLn are selectively connected to the word lines WL0 to WLn, which are arranged in every cell block, through byte select transistors T3. The gates of a plurality of byte select transistors T3 located along the same column are interconnected by one of byte select lines BSL0 to BSL3.

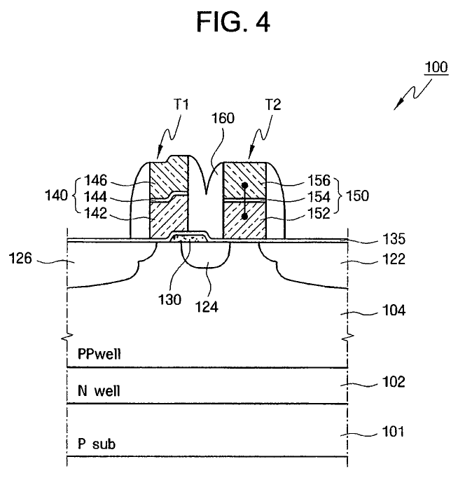

However, with reference to FIGS. 1 and 4, in the non-volatile memory integrated circuit device 1 according to the embodiments of the present invention, a second conduction-type (for example, an N-type) first well 102 may be formed within a first conduction-type (for example, a P-type) semiconductor substrate 101, and a first conduction-type (for example, a P-type) second well 104 may be formed within the first well 102. In this case, the cell blocks may be formed within the second well 104 and the byte select transistors Td may be formed within the first well 102.

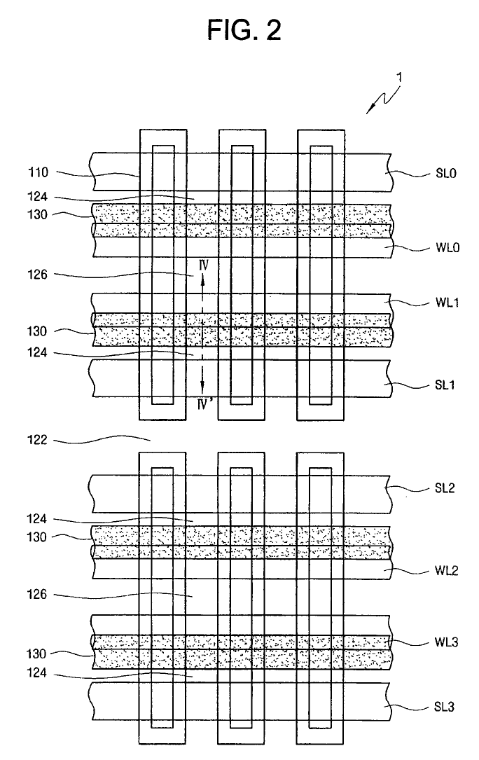

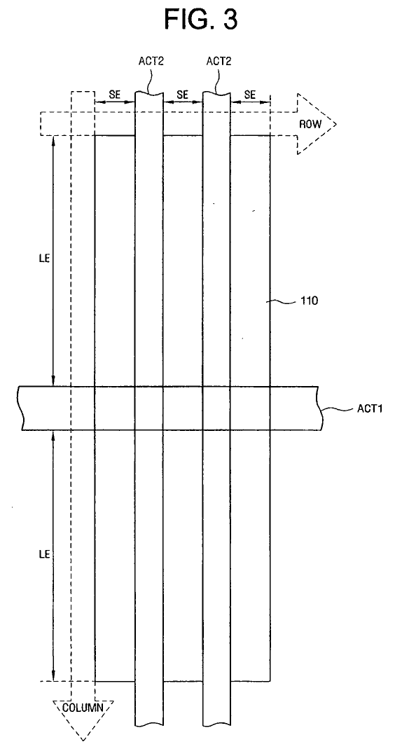

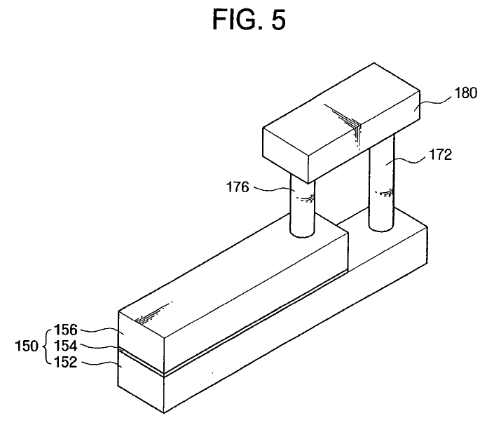

FIG. 2 is a layout diagram of a non-volatile memory integrated circuit device 1 according to an embodiment of the present invention. FIG. 3 is a diagram illustrating the active regions of FIG. 2. FIG. 4 is a sectional view of the non-volatile memory integrated circuit device taken along line IV-IV′ of FIG. 2. FIG. 5 is a perspective view illustrating the select gate of the non-volatile memory cell of the non-volatile memory integrated circuit device according to an embodiment of the present invention.

Referring first to FIGS. 2 and 3, in the non-volatile memory integrated circuit device 1 according to the embodiment of the present invention, a plurality of substantially rectangular field regions 110 is arranged on a semiconductor substrate in matrix form, thus defining active regions ACT1, ACT2.

The term “substantially rectangular” basically refers to a rectangle, but includes a polygon some or all of the four corners of which are chamfered for the efficiency of layout. The chamfering may be performed not only in a straight-line form, but also in a rounded form.

Furthermore, as shown in FIG. 3, the short side SE and long side LE of each of the substantially rectangular field regions 110 may be arranged parallel to the row direction ROW and column direction COLUMN of a matrix, respectively.

A plurality of first active regions ACT1, extending in the row direction ROW, and a plurality of second active regions ACT2, extending in the column direction COLUMN to cross the plurality of first active regions ACT1, are defined by the substantially rectangular field regions 110.

A tunneling-prevention dielectric layer pattern 130 may be arranged parallel to the row direction ROW on the semiconductor substrate in which the plurality of substantially rectangular field regions 110 is formed. A tunneling dielectric layer (not shown) is formed on the entire surface of the semiconductor substrate in which the tunneling-prevention dielectric layer pattern 130 is formed.

The word lines WL0, WL1, WL2, and WL3 and the select lines SL0, SL1, SL2, and SL3, extending parallel to the row direction ROW, are arranged on the semiconductor substrate in which the tunneling dielectric layer is formed.

In more detail, two select lines SL0 and SL1, or SL2 and SL3 cross the plurality of substantially rectangular field regions 110 arranged in the row direction ROW of the matrix. Two word lines WL0 and WL1, or WL2 and WL3 are interposed between the two select lines SL0 and SL1, or SL2 and SL3, and cross the plurality of substantially rectangular field regions 110 arranged in the row direction ROW of the matrix. More particularly, the word lines WL0, WL1, WL2, and WL3 may partially overlap the tunneling-prevention dielectric layer pattern 130.

Furthermore, a common source region 122 is formed within the first active region ACT1 between two select lines SL1 and SL2. A bit line junction region 126 is formed within the second active region ACT2 between two word lines WL0 and WL1, or WL2 and WL3. A floating junction region 124 is formed within the second active region ACT2 between each of the select lines SL0, SL1, SL2, and SL3 and each of the word lines WL0, WL1, WL2, and WL3.

Referring to FIG. 4, the non-volatile memory cell 100 of the non-volatile memory integrated circuit device (1 in FIG. 2) of the present invention includes the semiconductor substrate 101, the first well 102, the second well 104, the memory transistor T1, and the select transistor T2.

The second conduction-type (for example, the N-type) first well 102 is formed within the first conduction-type (for example, the P-type) semiconductor substrate 101. The first conduction-type (for example, the P-type) second well 104 is formed within the first well 102.

The semiconductor substrate 101 may be a silicon substrate, a Silicon On Insulator (SOI) substrate, a GaAs substrate, a SiGe substrate, a ceramic substrate, or a quartz substrate. For example, the semiconductor substrate 101 may be a single crystalline silicon substrate doped with a P-type impurity. The concentration of the P-type impurity may be in the range of about 10¹⁴ to 10¹⁵ atoms/cm³. Furthermore, the concentration of the N-type impurity of the first well 102 may be in the range of about 10¹⁵ to 10¹⁶ atoms/cm³, and the concentration of the P-type impurity of the second well 104 may be in the range of about 10¹⁶ to 10¹⁷ atoms/cm³.

A field region is formed within the semiconductor substrate 101, thus defining the active region. The field region may be generally made of Field Oxide (FOX) using a Shallow Trench Isolation (STI) or Local Oxidation of Silicon (LOCOS) method.

The memory transistor T1 and the select transistor T2 are formed within the second well 104. In an embodiment, the memory transistor T1 and the select transistor T2 respectively include a memory gate 140 and a select gate 150, which are formed on a tunneling dielectric layer 135. More particularly, in an embodiment, the non-volatile memory integrated circuit device includes the tunneling-prevention dielectric layer pattern 130, which is interposed between the semiconductor substrate 101 and the tunneling dielectric layer 135 and overlaps at least part of the memory gate 140. Although, in FIG. 4, the tunneling-prevention dielectric layer pattern 130 is illustrated as overlapping part of the floating junction region 124, the present invention is not limited thereto. The memory gate 140 is a stack-type gate in which a floating gate 142, an inter-gate dielectric layer 144, and a control gate 146 are stacked one on top of another. The select gate 150 is a stack-type gate in which a plurality of conductive films 152 and 156 are stacked one on top of another. A dielectric layer 154 is interposed between the plurality of conductive films 152 and 156. A spacer 160 may also be selectively formed on the sidewalls of the memory gate 140 and the select gate 150.

The tunneling dielectric layer 135 may be a single film made of SiO₂, SiON, La₂O₃, ZrO₂ or Al₂O₃, or a stack or combination film made of SiO₂, SiON, La₂O₃, ZrO₂ and Al₂O₃. The thickness of the tunneling dielectric layer 135 may be about 60 to 100 \acute{Å}, for example, 65 to 75 \acute{Å}, but is not limited thereto. Furthermore, the tunneling-prevention dielectric layer pattern 130 may be a single film made of SiO₂, SiON, La₂O₃, ZrO₂ or Al₂O₃, or a stack or mixed film made of SiO₂, SiON, La₂O₃, ZrO₂ and/or Al₂O₃. The tunneling-prevention dielectric layer pattern 130 may have a thickness greater than that of the tunneling dielectric layer 135. The thickness of the tunneling-prevention dielectric layer pattern 130 may be about 100 to 300 \acute{Å}, but is not limited thereto.

In a conventional non-volatile memory cell, electric charges are programmed or erased through the front surface of the tunneling dielectric layer below the memory gate using FN tunneling. That is, the tunneling region is the front surface of the tunneling dielectric layer of the memory gate. In the present invention, the tunneling-prevention dielectric layer pattern 130 is formed in order to reduce the area of the tunneling region. The region in which the tunneling-prevention dielectric layer pattern 130 and the tunneling dielectric layer 135 overlap each other is much thicker than the region in which only the tunneling dielectric layer 135 is formed. Therefore, if a voltage is applied to the memory gate 140, the second well 104, and the bit line junction region 126 to the extent that electric charges can perform FN tunneling only across the tunneling dielectric layer 135, the electric charges cannot perform FN tunneling across the region in which the tunneling-prevention dielectric layer pattern 130 and the tunneling dielectric layer 135 overlap each other. That is, the tunneling region is confined to the region in which only the tunneling dielectric layer 135 is formed below the memory gate 140.

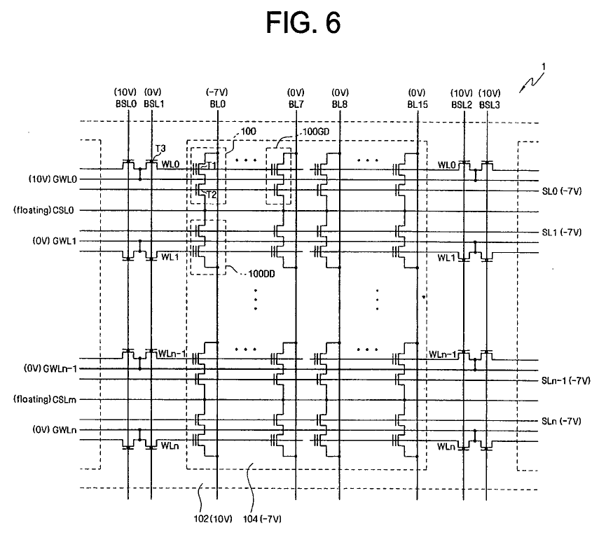

If the tunneling region is reduced as described above, the coupling ratio is increased at the time of the program/erase operations. Accordingly, the program/erase efficiency can be improved. This will be described in detail below with reference to FIGS. 6 to 10.

The floating gate 142 is formed on the tunneling dielectric layer 135, and may be formed of a polycrystalline silicon film doped with an impurity. The thickness of the floating gate 142 may be about 1000 to 3000 \acute{Å}, but is not limited thereto. The floating gate 142 serves to store electrical charges that determine the logic state of the non-volatile memory integrated circuit device.

The inter-gate dielectric layer 144 is formed on the floating gate 142, and may be a single film formed of an oxide film or a nitride film, or a stack or mixed film formed of an oxide film and a nitride film. For example, a stack film formed of an oxide film, a nitride film and an oxide film (a so-called “ONO film”) may be generally used as the inter-gate dielectric layer 144. The lower oxide film may have a thickness of 100 \acute{Å}, the nitride film may have a thickness of 100 \acute{Å}, and the upper oxide film may have a thickness of 40 \acute{Å}.

The control gate 146 is formed on the inter-gate dielectric layer 144. Although not shown in the drawings, a capping film may be further formed on the top of the control gate 146.

The plurality of conductive films 152 and 156 of the select gate 150 may be formed to have the same thicknesses and use the same materials as those of the floating gate 142 and the control gate 146, respectively.

The floating junction region 124 is located within the semiconductor substrate 101 between the memory gate 140 and the select gate 150. The bit line junction region 126 is located opposite the floating junction region 124 with respect to the memory gate 140. The common source region 122 is located opposite the floating junction region 124 with respect to the select gate 150. Although, in the drawings, the bit line junction region 126 and the common source region 122 are illustrated as having a Lightly Doped Drain (LDD) structure, in which a low-concentration impurity is shallowly doped and a high-concentration impurity is deeply doped, and the floating junction region 124 is shallowly doped only with a low-concentration impurity, the present invention is not limited thereto. For example, the floating junction region 124 may also have an LDD structure, and the bit line junction region 126 and the common source region 122 may be shallowly doped only with a low-concentration impurity.

The plurality of conductive films 152 and 156 of the select gate 150 may be electrically connected to each other. The conductive films 152 and 156 may be electrically connected to each other using a butting contact, as shown in FIG. 5. That is, a contact 172 connected to the conductive film 152, and a contact 176 connected to the conductive film 156 can be connected to the same metal line 180 such that the same electrical signal can be applied to the plurality of conductive films 152 and 156.

Hereinafter, the operation of the above-mentioned non-volatile memory integrated circuit device will be described with reference to FIGS. 6 to 10 and Table 1.

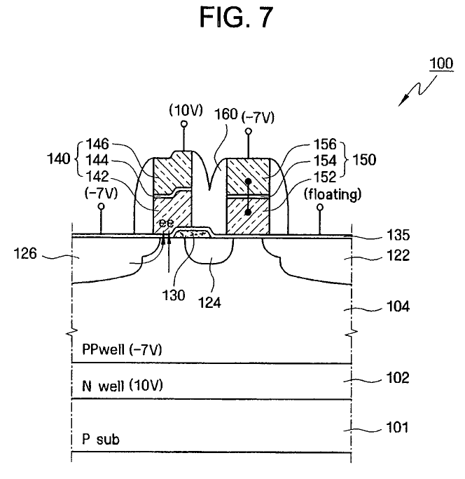

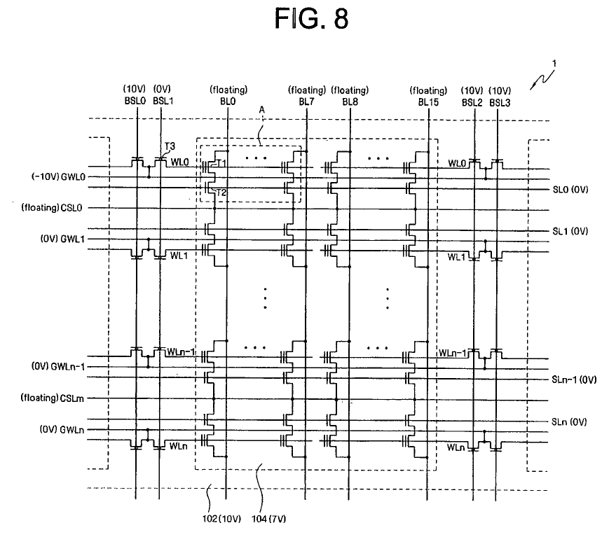

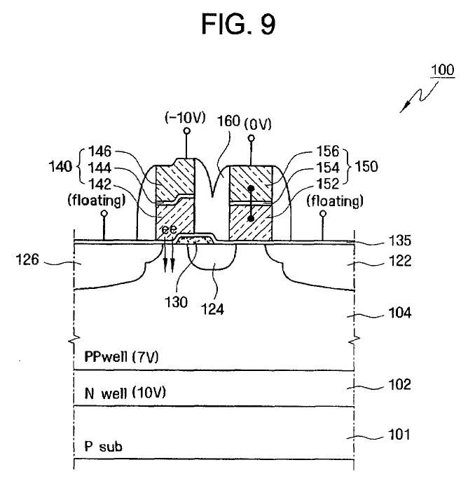

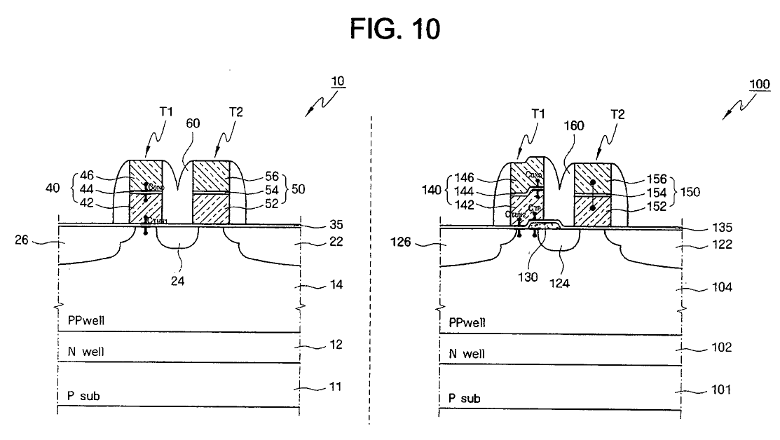

FIGS. 6 and 7 are diagrams illustrating the program operation of the non-volatile memory integrated circuit device according to an embodiment of the present invention. FIGS. 8 and 9 are diagrams illustrating the erase operation of the non-volatile memory integrated circuit device according to an embodiment of the present invention. FIG. 10 is a diagram illustrating the coupling ratio of a non-volatile memory cell used in a conventional non-volatile memory integrated circuit device and the coupling ratio of the non-volatile memory cell used in the non-volatile memory integrated circuit device according to an embodiment of the present invention.

Table 1 shows a list of operating voltages during the respective operations of the non-volatile memory integrated circuit device. It is to be understood that Table 1 illustrates only exemplary operating voltages, and that the present invention does not exclude other operating voltages.

TABLE 1

| | | Word | Select | | Common | Second |
|---|---|---|---|---|---|---|
| | | Line | Line | Bit Line | Source | Well |
| Program | Select | 10 V | −7 V | −7 V | floating | −7 V |
| | Non-select | 0 V | −7 V | 0 V | floating | −7 V |
| Erase | Select | −10 V | 0 V | floating | floating | 7 V |
| | Non-select | 0 V | 0 V | floating | floating | 7 V |

Referring to FIGS. 6 and 7 and Table 1, the program operation is an operation of charging the floating gate 142 of the memory transistor T1 with electrical charges that determine the logic state. Since a program mechanism employs FN tunneling, the bit line BL0 coupled to a non-volatile memory cell 100 selected to be programmed is set at a low level (for example, −7V), the word line WL0 is set at a high level (for example, 10V), and the second well 104 is supplied with a low voltage (for example, −7V). Accordingly, a charging path for electrical charges is formed between the bit line junction 126 and floating gate 142 of the selected non-volatile memory cell 100 and between the second well 104 and the floating gate 142. Furthermore, the select line SL0 is supplied with a low level voltage (for example, −7V), thereby preventing the floating junction 124 and the common source 122 from being electrically connected to each other.

Referring to FIG. 6 and Table 1, the non-selected non-volatile memory cell 100GD sharing the same word lines WL0 with the selected non-volatile memory cell 100 may be unintentionally programmed by a gate disturb phenomenon. To prevent such unintentional programming, the bit line BL7 coupled to the non-selected non-volatile memory cell 100GD is supplied with, for example, 0V.

Furthermore, the non-selected non-volatile memory cell 100DD that shares the same bit line with the selected non-volatile memory cell 100 may be unintentionally programmed by a drain disturbance phenomenon. To prevent such unintentional programming, the word line WL1 coupled to the non-selected non-volatile memory cell 100DD is supplied with, for example, 0V.

Referring to FIGS. 8 and 9 and Table 1, the erase operation is an operation of discharging electrical charges from the floating gate 142 of the memory transistor T1. For example, eight non-volatile memory cells A (eight non-volatile memory cells constitute a unit, that is, a byte unit) may be erased at the same time, but the present invention is not limited thereto. Since an erase mechanism employs FN tunneling, the word line WL0 coupled to the eight non-volatile memory cells A selected to be erased is set at a low level (for example, −10V), the second well 104 is supplied with a high voltage (for example, 7V), and the bit lines BL0 to BL7 are floated. Therefore, a discharge path for electrical charges is formed between the floating gates 142 of the selected eight non-volatile memory cells A and the second well 104.

Since, in an embodiment of the present invention, the tunneling-prevention dielectric layer pattern 130 partially overlaps the memory gate 140, the tunneling region is confined only to a region in the tunneling dielectric layer 135 below the memory gate 140, compared to the prior art. If the tunneling region is reduced as described above, the coupling ratio can be increased at the time of the program/erase operations, and program/erase efficiency can be improved accordingly.

This will be described in detail with reference to FIG. 10. As shown in the left view of FIG. 10, the coupling ratios during conventional program and erase operations can be expressed by Equations 1 and 2, respectively. As shown in the right view of FIG. 10, the coupling ratios during the program and erase operations according to an embodiment of the present invention can be expressed by Equations 3 and 4, respectively.

$$\begin{matrix}{K}_{P 1} = \frac{{C}_{ONO}}{{C}_{TOT}} = \frac{{C}_{ONO}}{{C}_{ONO} + {C}_{TUN 1}} & ( 1 ) \\ {K}_{E 1} = 1 - \frac{{C}_{TUN 1}}{{C}_{TOT}} = 1 - \frac{{C}_{TUN 1}}{{C}_{ONO} + {C}_{TUN 1}} & ( 2 ) \\ {K}_{P 2} = \frac{{C}_{ONO}}{{C}_{TOT}} = \frac{{C}_{ONO}}{{C}_{ONO} + {C}_{TP} + {C}_{TUN 2}} & ( 3 ) \\ {K}_{E 2} = 1 - \frac{{C}_{TUN 2}}{{C}_{TOT}} = 1 - \frac{{C}_{TUN 2}}{{C}_{ONO} + {C}_{TP} + {C}_{TUN 2}} & ( 4 )\end{matrix}$$

where K_{P1} is the coupling ratio during the conventional program operation, K_{E1} is the coupling ratio during the conventional erase operation, C_{TUN1} is the capacitance of the tunneling dielectric layer 35 below the memory gate 40, C_{ONO} is the capacitance of an inter-gate dielectric layer 44, C_{TOT} is the sum of all capacitances, K_{P2} is the coupling ratio during the program operation of the present invention, K_{E2} is the coupling ratio during the erase operation of the present invention, C_{TUN2} is the capacitance of the tunneling region (that is, the capacitance of the region in which only the tunneling dielectric layer 135 is formed below the memory gate 140), C_{TP} is the capacitance of the tunneling-preventing region (that is, the capacitance of the region in which the tunneling dielectric layer 135 and the tunneling-prevention dielectric layer pattern 130 overlap each other below the memory gate 140), C_{ONO} is the capacitance of the inter-gate dielectric layer 144, and C_{TOT} is the sum of all capacitances.

Furthermore, if, for ease of description, it is assumed that in the right view of FIG. 10, the area of the region in which only the tunneling dielectric layer 135 is formed below the memory gate 140 and the area of the region in which the tunneling dielectric layer 135 and the tunneling-prevention dielectric layer pattern 130 overlap each other below the memory gate 140 are the same, it can be understood from the following description that the program/erase coupling ratios in the non-volatile memory integrated circuit device of the present invention are increased compared to the conventional art.

That is, when Equation 3 is compared with Equation 1, C_{TUN1} is reduced to C_{TUN2} and C_{TP} is added in the denominator of Equation 3. There is the relationship C_{TUN1}=2C_{TUN2}>C_{TUN2}+C_{TP}, therefore the coupling ratio K_{P2} during the program operation of the present invention is higher than the coupling ratio K_{P1} during the conventional program operation.

Furthermore, when Equation 4 is compared with Equation 2, C_{TUN1} is reduced to C_{TUN2} in the numerator of Equation 4. Accordingly, the coupling ratio K_{E2} during the erase operation of the present invention is higher than the coupling ratio K_{E1} during the conventional erase operation.

That is, since both the coupling ratio K_{P2} during the program operation and the coupling ratio K_{E2} during the erasing operation are increased, program/erase efficiency are increased.

Reference numerals of FIG. 10 that have not been described are described as follows. Reference numeral 11 denotes a semiconductor substrate, reference numeral 12 denotes a first well, reference numeral 14 denotes a second well, reference numeral 22 denotes a common source region, reference numeral 24 denotes a floating junction region, reference numeral 26 denotes a bit line junction region, reference numeral 42 denotes a floating gate, reference numeral 46 denotes a control gate, reference numeral 50 denotes a select gate, reference numerals 52 and 56 denote conductive films, and reference numeral 54 denotes a dielectric layer.

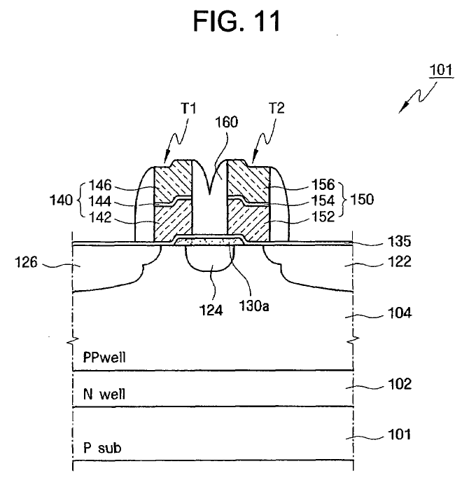

FIG. 11 is a sectional view of a non-volatile memory integrated circuit device according to another embodiment of the present invention.

Referring to FIG. 11, the non-volatile memory integrated circuit device is substantially the same as that of FIG. 4 except that a tunneling-prevention dielectric layer pattern 130a sufficiently extends to overlap not only a floating junction region 124 but also at least part of a select gate 150.

In this case, the size of the tunneling-prevention dielectric layer pattern 130a increases to more than that of FIG. 4, therefore patterning can be performed even if the size of the non-volatile memory cell is reduced.

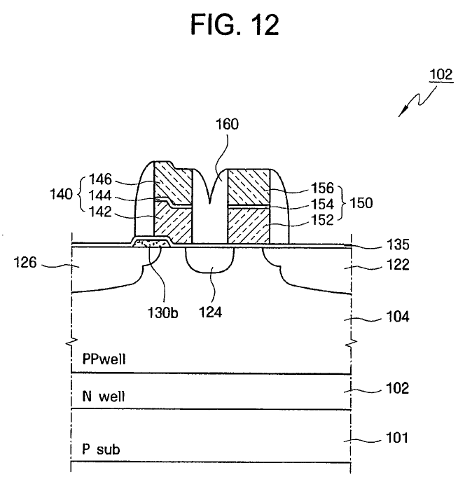

FIG. 12 is a sectional view of a non-volatile memory integrated circuit device according to still another embodiment of the present invention.

The non-volatile memory integrated circuit device of FIG. 12 is substantially the same as that of FIG. 4 except that a tunneling-prevention dielectric layer pattern 130b does not overlap at least some of a floating junction region 124 and overlaps at least part of a bit line junction region 126.

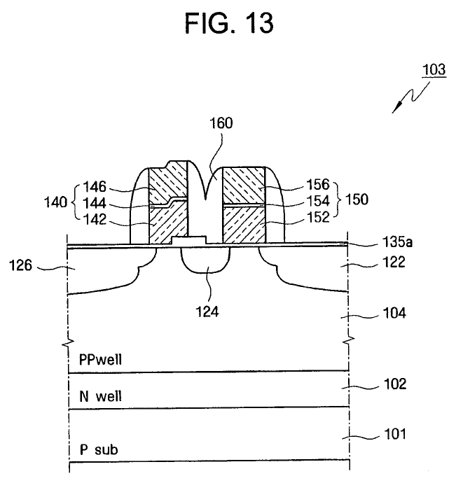

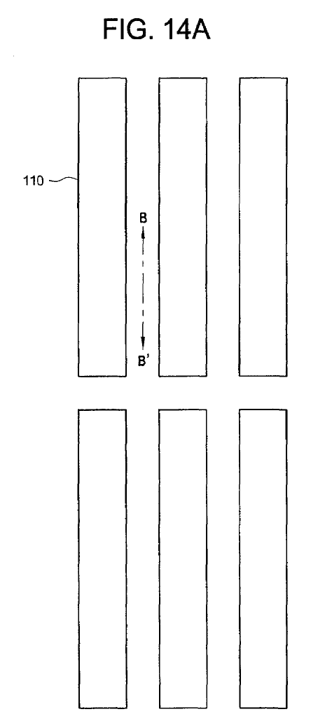

FIG. 13 is a sectional view of a non-volatile memory integrated circuit device according to still another embodiment of the present invention.

Referring to FIG. 13, the non-volatile memory integrated circuit device is substantially the same as that of FIG. 4 except that a separate tunneling-prevention dielectric layer pattern (refer to reference numeral 130 of FIG. 4) is not formed and the thickness of a tunneling dielectric layer 135a below a memory gate 140 is not constant.

In more detail, the tunneling dielectric layer below the memory gate 140 includes a floating junction region (124)-side tunneling dielectric layer and a bit line junction region (126)-side tunneling dielectric layer 135 having different thicknesses. Furthermore, either the floating junction region (124)-side tunneling dielectric layer or the bit line junction region (126)-side tunneling dielectric layer is thicker than the tunneling dielectric layer below the select gate 150. Although, in FIG. 13, the floating junction region (124)-side tunneling dielectric layer is thicker than the bit line junction region (126)-side tunneling dielectric layer and the tunneling dielectric layer below the select gate 150 has the same thickness as the bit line junction region (126)-side tunneling dielectric layer, the present invention is not limited thereto. For example, the bit line junction region (126)-side tunneling dielectric layer may be thicker than the floating junction region (124)-side tunneling dielectric layer, and the tunneling dielectric layer 135 below the select gate 150 may have the same thickness as the floating junction region (124)-side tunneling dielectric layer.

It will be apparent to those skilled in the art that the modified embodiments of FIGS. 11 to 13 may be implemented separately or in combination with each other.

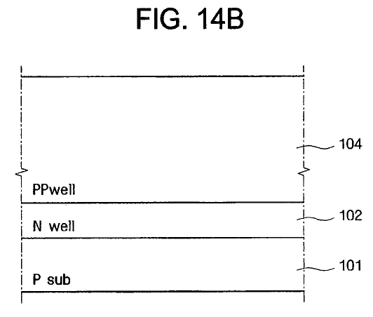

FIGS. 14A to 17B are diagrams illustrating a method of fabricating a non-volatile memory cell constituting part of the non-volatile memory integrated circuit device according to an embodiment of the present invention.

Referring to FIGS. 14A and 14B, an N-type first well 102 is formed within a P-type semiconductor substrate 101. The first well 102 may be formed using diffusion or ion implantation such that an N-type impurity has a concentration of about 10¹⁶ to 10¹⁸ atoms/cm³.

A P-type second well 104 is formed within the first well 102. The second well 104 may be formed using diffusion or ion implantation so that a P-type impurity has a concentration of about 10¹⁷ to 10¹⁸ atoms/cm³.

Thereafter, a plurality of substantially rectangular field regions 110 is formed within the semiconductor substrate 101 in a matrix form, thus defining active regions. The substantially rectangular field regions 110 are arranged such that the short sides and long sides thereof are aligned parallel to the row and column directions of a matrix, respectively.

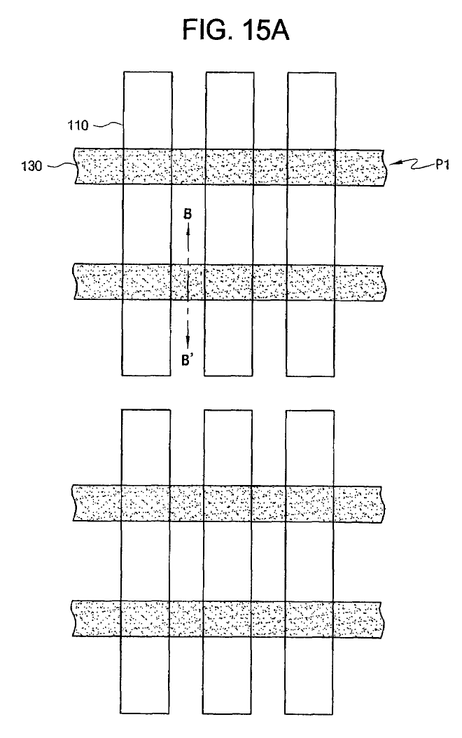

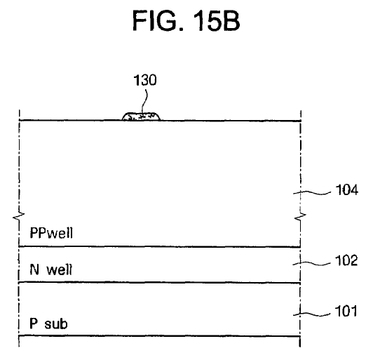

Referring to FIGS. 15A and 15B, a tunneling dielectric layer is formed on the semiconductor substrate 101, and a tunneling-prevention dielectric layer pattern 130 is formed by performing primary patterning P1 on the tunneling dielectric layer. In more detail, the tunneling-prevention dielectric layer pattern 130 may be formed to have a thickness of about 100 to 300 \acute{Å} using a single film made of SiO₂, SiON, La₂O₃, ZrO₂ or Al₂O₃, or a stack or mixed film made of SiO₂, SiON, La₂O₃, ZrO₂ and/or Al₂O₃ through CVD or ALD.

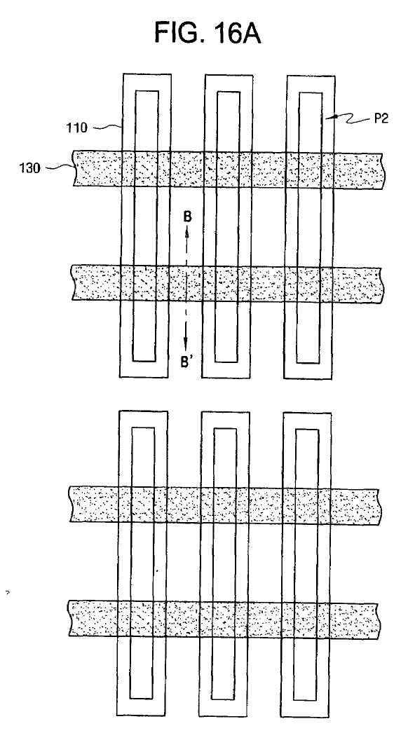

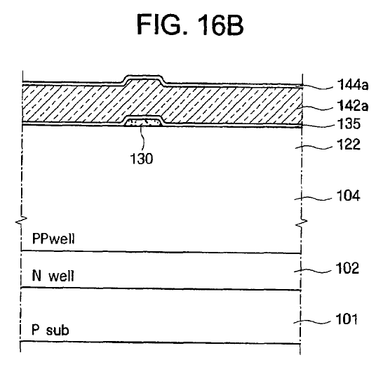

Referring to FIGS. 16A and 16B, the tunneling dielectric layer 135 is formed on the tunneling-prevention dielectric layer pattern 130 and the semiconductor substrate 101. The tunneling dielectric layer 135 may be formed to have a thickness of about 60 to 100 \acute{Å}, preferably about 70 to 80 \acute{Å}, using a single film made of SiO₂, SiON, La₂O₃, ZrO₂ or Al₂O₃, or a stack or mixed film made of SiO₂, SiON, La₂O₃, ZrO₂, and/or Al₂O₃ through CVD or ALD.

A first conductive film 142a used to form a floating gate and a dielectric layer 144a used to form an inter-gate dielectric layer are sequentially formed on the tunneling dielectric layer 130. The first conductive film may be formed to have a thickness of 1000 to 3000 \acute{Å} using a polycrystalline silicon film doped with an impurity through CVD.

The dielectric layer may be formed using a single film formed of an oxide film or a nitride film, or a stack or mixed film formed of an oxide film and a nitride film. For example, the dielectric layer may be formed using a stack film formed of an oxide film, a nitride film, and an oxide film (a so-called “ONO film”). The stack film formed of an oxide film, a nitride film and an oxide film may be formed to have thicknesses of 100 \acute{Å}, 100 \acute{Å}, and 40 \acute{Å}, respectively, through CVD or ALD.

A dielectric layer pattern 144a and a first conductive film pattern 142a are formed by sequentially performing secondary patterning P2 on the dielectric layer and the first conductive film.

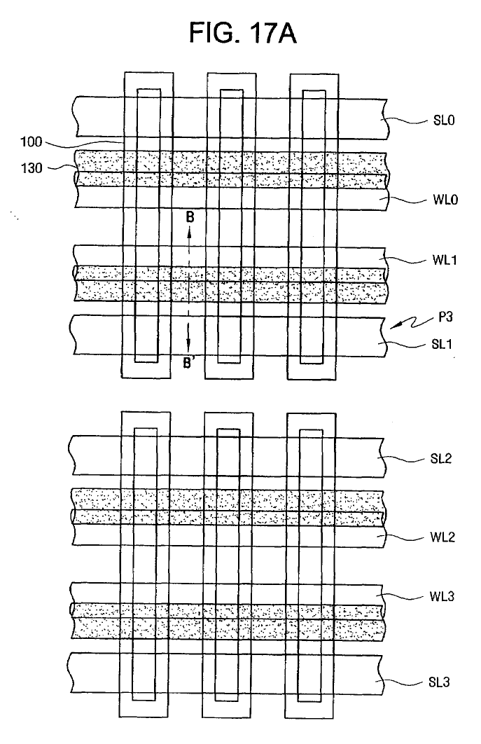

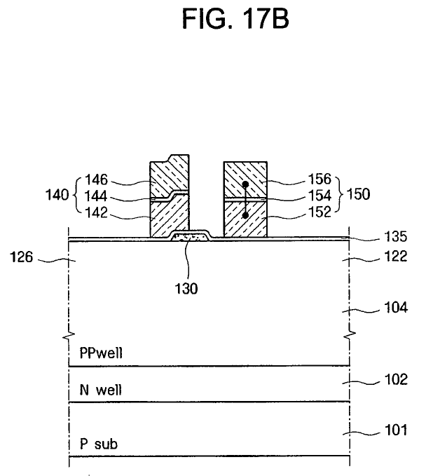

Referring to FIGS. 17A and 17B, a second conductive film used to form the control gate 146 is formed on the product of the second patterning P2. The second conductive film may be formed of a single film formed of a polycrystalline silicon film doped with an impurity, a metal silicide film or a metal film, or a multi-layer film formed of a metal film/a metal barrier film, a metal film/a polycrystalline silicon film doped with an impurity, a metal silicide film/a metal silicide film, and a metal silicide film/a polycrystalline silicon film doped with an impurity. The metal may be W, Ni, Co, Ru—Ta, Ni—Ti, Ti—Al—N, Zr, Hf, Ti, Ta, Mo, Ta—Pt, Ta—Ti or W—Ti, the metal barrier material may be WN, TiN, TaN, TaCN or MoN, and the metal silicide may be WSix, CoSix or NiSix. However, the present invention is not limited thereto.

A memory gate 140, which is composed of the control gate 146, the inter-gate dielectric layer 144 and the floating gate 142, and the select gate 150, which is spaced apart from the memory gate 140 by a predetermined distance, are formed by sequentially performing third patterning P3 on the second conductive film, the dielectric layer pattern 144a of FIG. 16B, and the first conductive film pattern 142a of FIG. 16B.

Referring back to FIGS. 2 to 4, an N-type low-concentration impurity is implanted at a low energy state using the product of the third patterning P3 as a mask.

Thereafter, the spacers 160 are formed on both sidewalls of the memory gate 140 and the select gate 150. In an embodiment of the present invention, the gap between the memory gate 140 and the select gate 150 is not sufficiently wide, therefore the spacer 160 formed on one side of the memory gate 140 and the spacer 160 formed on one side of the select gate 150 opposite the memory gate 140 can be connected to each other without being completely separated from each other.

Thereafter, the bit line junction region 126, the floating junction region 124, and the common source region 122 are formed by implanting an N-type high-concentration impurity at a high energy state using the memory gate 140 and the select gate 150 with the spacers 160 formed thereon as masks.

If the spacer 160 formed on one sidewall of the memory gate 140 and the spacer 160 formed on one sidewall of the select gate 150 opposite the memory gate 140 are interconnected as described above, an N-type high-concentration impurity region may not be formed in the floating junction region 124. In contrast, the bit line junction region 126 and the common source region 122 may be of an LDD type, in which a low-concentration impurity is doped shallowly and a high-concentration impurity is doped deeply. Therefore, the floating junction region 124 may be formed thin compared with the bit line junction region 126 and the common source region 122.

Thereafter, by performing the step of forming wiring so that electrical signals can be input and output to and from the memory cell, the step of forming a passivation layer on the substrate, and the step of packaging the substrate according to processes that are well known to those skilled in the semiconductor field, the non-volatile memory integrated circuit device is completed.

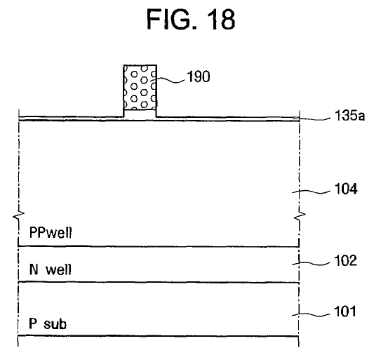

FIG. 18 is a sectional view illustrating a method of fabricating a non-volatile memory integrated circuit device according to another embodiment of the present invention.

Referring to FIG. 18, the method of fabricating the non-volatile memory integrated circuit device according to another embodiment of the present invention is substantially the same as that according to the other embodiments of the present invention described herein, except that the step of forming the tunneling-prevention dielectric layer pattern (refer to 130 of FIG. 15b) is omitted and the thickness of the tunneling dielectric layer 135a is not constant A tunneling dielectric layer below the memory gate 140 includes a floating junction region (124)-side tunneling dielectric layer and a bit line junction region (126)-side tunneling dielectric layer having different thicknesses. Furthermore, either the floating junction region (124)-side tunneling dielectric layer or the bit line junction region (126)-side tunneling dielectric layer is thicker than the tunneling dielectric layer below the select gate 150.

The tunneling dielectric layer 135a having the above-described configuration may be formed by forming a dielectric layer to have a thickness of about 160 to 380 \acute{Å}, forming a photoresist pattern 190 on the dielectric layer, and time-etching a dielectric layer using the photoresist pattern 190 as a mask According to the non-volatile memory integrated circuit device and method of fabricating the device, the coupling ratios during program and erase operations can be increased, thereby improving program/erase efficiency.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A non-volatile memory integrated circuit device comprising:
a semiconductor substrate;
a tunneling dielectric layer formed on the semiconductor substrate;
a memory gate and a select gate formed on the tunneling dielectric layer, the memory gate and the select gate being spaced apart from each other,
a floating junction region formed within the semiconductor substrate between the memory gate and the select gate, a bit line junction region formed opposite the floating junction region with respect to the memory gate, and a common source region formed opposite the floating junction region with respect to the select gate; and
a tunneling-prevention dielectric layer pattern interposed between the semiconductor substrate and the tunneling dielectric layer and configured to overlap part of the memory gate.

2. The non-volatile memory integrated circuit device of claim 1, wherein the tunneling-prevention dielectric layer pattern is thicker than the tunneling dielectric layer.

3. The non-volatile memory integrated circuit device of claim 2, wherein the tunneling-prevention dielectric layer pattern has a thickness of about 100 to 300 \acute{Å} and the tunneling dielectric layer has a thickness of about 60 to 80 \acute{Å}.

4. The non-volatile memory integrated circuit device of claim 1, wherein the tunneling-prevention dielectric layer pattern is a single film made of SiO₂, SiON, La₂O₃, ZrO₂ or Al₂O₃, or a stack or mixed film made of SiO₂, SiON, La₂O₃, ZrO₂, and/or A₂O₃.

5. The non-volatile memory integrated circuit device of claim 1, wherein the tunneling-prevention dielectric layer pattern overlaps at least part of the floating junction region.

6. The non-volatile memory integrated circuit device of claim 5, wherein the tunneling-prevention dielectric layer pattern overlaps at least part of the select gate.

7. The non-volatile memory integrated circuit device of claim 1, wherein the tunneling-prevention dielectric layer pattern overlaps at least part of the bit line junction region.

8. The non-volatile memory integrated circuit device of claim 1, wherein the semiconductor substrate is a first conduction type, and comprises a second conduction-type first well, which is formed within the semiconductor substrate, and a first conduction-type second well, which is formed within the first well.

9. The non-volatile memory integrated circuit device of claim 1, wherein the memory gate has a stack structure in which a floating gate and a control gate which are electrically isolated from each other, are stacked one on top of another.

10. The non-volatile memory integrated circuit device of claim 1, wherein the select gate has a stack structure in which a plurality of conductive films which are electrically connected to each other through a butting contact is stacked one on top of another.

11. A non-volatile memory integrated circuit device comprising:
a semiconductor substrate;
a tunneling dielectric layer formed on the semiconductor substrate;
a memory gate and a select gate formed on the tunneling dielectric layer, the memory gate and the select gate being spaced apart from each other, and
a floating junction region formed within the semiconductor substrate between the memory gate and the select gate, a bit line junction region formed opposite the floating junction region with respect to the memory gate, and a common source region formed opposite the floating junction region with respect to the select gate,
wherein a tunneling dielectric layer below the memory gate comprises a floating junction region-side tunneling dielectric layer and a bit line junction region-side tunneling dielectric layer having different thicknesses, and
wherein any one of the floating junction region-side tunneling dielectric layer and the bit line junction region-side tunneling dielectric layer is thicker than a tunneling dielectric layer below the select gate.

12. The non-volatile memory integrated circuit device of claim 11, wherein the floating junction region-side tunneling dielectric layer is thicker than the bit line junction region-side tunneling dielectric layer, and the tunneling dielectric layer below the select gate has a thickness identical to that of the bit line junction region-side tunneling dielectric layer.

13. The non-volatile memory integrated circuit device of claim 11, wherein the bit line junction region-side tunneling dielectric layer is thicker than the floating junction region-side tunneling dielectric layer, and the tunneling dielectric layer below the select gate has a thickness identical to that of the floating junction region-side tunneling dielectric layer.

14. The non-volatile memory integrated circuit device of claim 11, wherein the semiconductor substrate is a first conduction type, and comprises a second conduction-type first well, which is formed within the semiconductor substrate, and a first conduction-type second well, which is formed within the first well.

15. A non-volatile memory integrated circuit device comprising:
a first conduction-type semiconductor substrate;
a second conduction-type first well formed within the semiconductor substrate;
a first conduction-type second well formed within the first well;
a tunneling dielectric layer formed on the second well;
a memory gate and a select gate formed on the tunneling dielectric layer, the memory gate and the select gate being spaced apart from each other, and
a floating junction region formed within the semiconductor substrate between the memory gate and the select gate, a bit line junction region formed opposite the floating junction region with respect to the memory gate, and a common source region formed opposite the floating junction region with respect to the select gate,
wherein the tunneling dielectric layer below the memory gate varies in thickness on the floating junction region side and the bit line junction region side.

16. The non-volatile memory integrated circuit device of claim 15, wherein:
the tunneling dielectric layer below the memory gate is thicker on a floating junction region side than on a bit line junction region side; and
the tunneling dielectric layer below the select gate has a thickness identical to that of the bit line junction region-side tunneling dielectric layer below the memory gate.

17. The non-volatile memory integrated circuit device of claim 15, wherein:
the tunneling dielectric layer below the memory gate is thicker on a bit line junction region side than on a floating junction region side; and
the tunneling dielectric layer below the select gate has a thickness identical to that of the floating junction region-side tunneling dielectric layer below the memory gate.

18. A method of fabricating a non-volatile memory integrated circuit device, the method comprising:
forming a tunneling-prevention dielectric layer pattern on a semiconductor substrate;
forming a tunneling dielectric layer on the tunneling-prevention dielectric layer pattern and the semiconductor substrate;
forming a memory gate and a select gate on the tunneling dielectric layer to be spaced apart from each other, wherein part of the memory gate overlaps the tunneling-prevention dielectric layer pattern; and
forming a floating junction region within the semiconductor substrate between the memory gate and the select gate, a bit line junction region opposite the floating junction region with respect to the memory gate, and a common source region opposite the floating junction region with respect to the select gate.

19. The method of claim 18, wherein the tunneling-prevention dielectric layer pattern overlaps at least part of the floating junction region.

20. The method of claim 19, wherein the tunneling-prevention dielectric layer pattern overlaps at least part of the select gate.

21. The method of claim 18, wherein the tunneling-prevention dielectric layer pattern overlaps at least part of the bit line junction region.

22. A method of fabricating a non-volatile memory integrated circuit device, the method comprising:
forming a tunneling dielectric layer on a semiconductor substrate;
forming a memory gate and a select gate on the tunneling dielectric layer to be spaced apart from each other, and
forming a floating junction region within the semiconductor substrate between the memory gate and the select gate, a bit line junction region opposite the floating junction region with respect to the memory gate, and a common source region opposite the floating junction region with respect to the select gate,
wherein forming the tunneling dielectric layer is performed in such a way that the tunneling dielectric layer below the memory gate comprises a floating junction region-side tunneling dielectric layer and a bit line junction region-side tunneling dielectric layer, which have different thicknesses, and any one of the floating junction region-side tunneling dielectric layer and the bit line junction region-side tunneling dielectric layer is thicker than the tunneling dielectric layer below the select gate.
